(19) United States
(12) Patent Application Publication
(10) Pub. No.: US 2016/0192538 A1
(43) Pub. Date: Jun. 30, 2016

(54) HEAT DISSIPATION DEVICE AND ELECTRONIC DEVICE

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: BO YANG, Wuhan (CN); XU LI, Wuhan (CN)

(21) Appl. No.: 14/612,947

(22) Filed: Feb. 3, 2015

(30) Foreign Application Priority Data
Dec. 25, 2014 (CN) 201410818920.4

(51) Int. Cl. H05K 7/20

(52) U.S. Cl. CPC H05K 7/20145

(57) ABSTRACT

A heat dissipation device includes a first air duct mounted on a circuit board. The circuit board includes a top panel, a sidewall extending from the top panel and a vent structure connected to the top panel and the sidewall. The vent structure includes a guiding panel extending from the top panel and a shielding panel extending from the guiding panel. The guiding panel can guide airflow to a component located between the shielding panel and the circuit board to dissipate heat from the component.

### CROSS-REFERENCE TO RELATED APPLICATIONS

This application claims priority to Chinese Patent Application No. 201410818920.4 filed on Dec. 25, 2014, the contents of which are hereby incorporated by reference.

### FIELD

The subject matter herein generally relates to a heat dissipation device of an electronic device, and more particularly to a heat dissipation device which can dissipate heat effectively from components of a circuit board.

### BACKGROUND

A circuit board is very important in an electronic device. The circuit board generally includes a plurality of components, such as a voltage regulation module, a memory card, and so on. Heat will be generated from the components when the electronic device is working.

### BRIEF DESCRIPTION OF THE DRAWINGS

Implementations of the present technology will now be described, by way of example only, with reference to the attached figures.

FIG. 1 is an exploded, isometric view of an electronic device in accordance with an embodiment.

FIG. 2 is an isometric view of a first air duct of FIG. 1.

FIG. 3 is similar to FIG. 2, but viewed from a different angle.

FIG. 4 is an assembled, isometric view of the electronic device of FIG. 1.

FIG. 5 is similar to FIG. 4, but viewed from a different angle.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

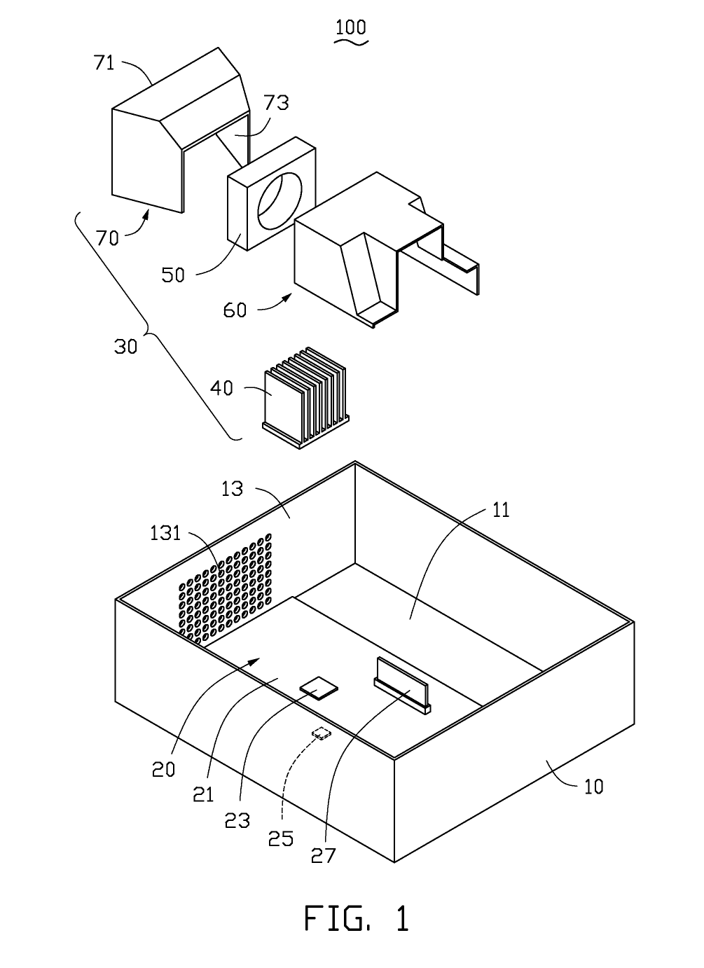

FIG. 1 illustrates an embodiment of an electronic device 100 including an enclosure 10 and a circuit board 20. The enclosure 10 includes a bottom plate 11 and a side plate 13. The side plate 13 extends perpendicularly from the bottom plate 11. A plurality of through holes 131 are defined in the side plate 13.

The circuit board 20 is mounted on the bottom plate 11. The circuit board 20 includes a main body 21, a CPU 23, a first component 25, and a second component 27. The CPU 23, the first component 25, and the second component 27 are mounted on the main body 21 and generate heat when in operation. In at least one embodiment, the first component 25 is a voltage regulation module configured to provide a stable voltage for the CPU, the second component 27 is a memory card or a video card.

The electronic device 100 further includes a heat dissipation device 30 configured to dissipate heat from the CPU 23, the first component 25, and the second component 27.

The heat dissipation device 30 can include a heat sink 40, a fan 50, a first air duct 60, and a second air duct 70.

The second air duct 70 can include an inlet vent 71 and an outlet vent 73 communicating with the inlet vent 71. In at least one embodiment, an area of the inlet vent 71 is larger than that of the outlet vent 73.

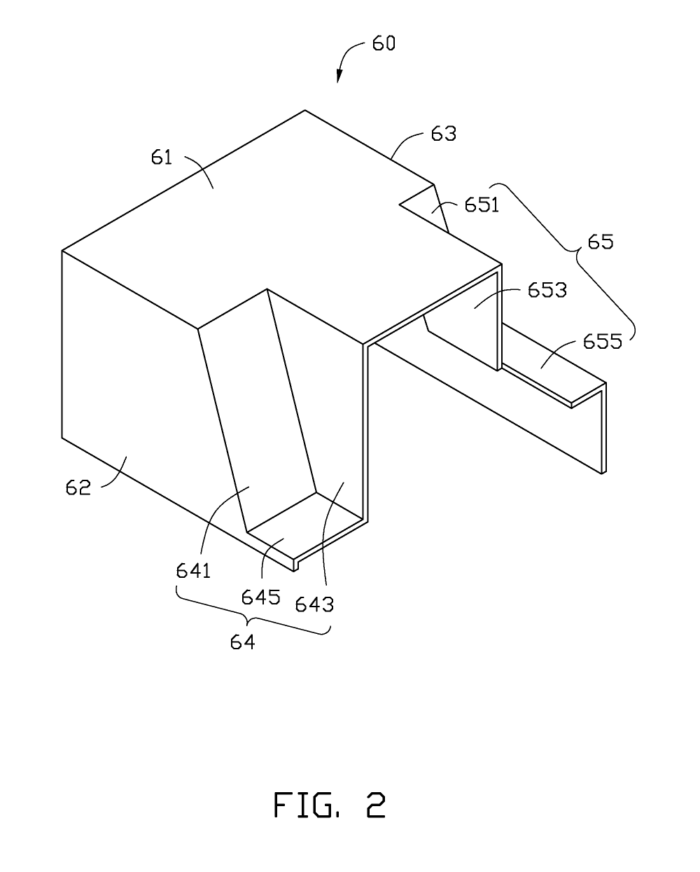

FIG. 2 illustrates the first air duct 60 including a top panel 61, a first sidewall 62 perpendicular to the top panel 61, and a second sidewall 63 parallel to the first sidewall 62. The first sidewall 62 and the second sidewall 63 extend from two opposite sides of the top panel 61. In at least one embodiment, the top panel 61 has a “T” configuration. The first air duct 60 further includes a first vent structure 64 and a second vent structure 65. The first vent structure 64 is located at a same side as the first sidewall 62, and the second vent structure 65 is located at a same side as the second sidewall 63.

The first vent structure 64 is connected to the first sidewall 62 and the top panel 61. The first vent structure 64 can include a first guiding panel 641 sloped from the top panel 61, a first baffle 643 extending perpendicularly from the top panel 61, and a first shielding panel 645 extending from the first guiding panel 641. The first guiding panel 641 is connected perpendicularly to the first panel 643 and the first sidewall 62. An obtuse angle is defined by the first guiding panel 641 and the top panel 61. The first shielding panel 645 is connected perpendicularly to the first baffle 643 and the first sidewall 62. The first shielding panel 645 is substantially parallel to the top panel 61. An obtuse angle is defined between the first guiding panel 641 and the first shielding panel 645.

The second vent structure 65 is connected to the second sidewall 63 and the top panel 61. The second vent structure 65 can include a second guiding panel 651 slantingly extending from the top panel 61, a second baffle 653 extending perpendicularly from the top panel 61, and a second shielding panel 655 extending from the second guiding panel 651. The second guiding panel 651 is connected perpendicularly to the second panel 653 and the second sidewall 63. An obtuse angle is defined by the second guiding panel 651 and the top panel 61. The second shielding panel 655 is connected perpendicularly to the second baffle 653 and the second sidewall 63. The second shielding panel 655 is substantially parallel to the top panel 61. An obtuse angle is defined between the second guiding panel 651 and the second shielding panel 655. In at least one embodiment, the first guiding panel 641 is substantially parallel to the second guiding panel 651, a length of the second shielding panel 655 in a first direction, substantially parallel to the first sidewall 62, is greater than that of the first shielding panel 654; and a length of the second sidewall 63 in the first direction is greater than the first sidewall 62. A distance between the first sidewall 62 and the second sidewall 63 is greater than a distance between the first baffle 643 and the second baffle 653.

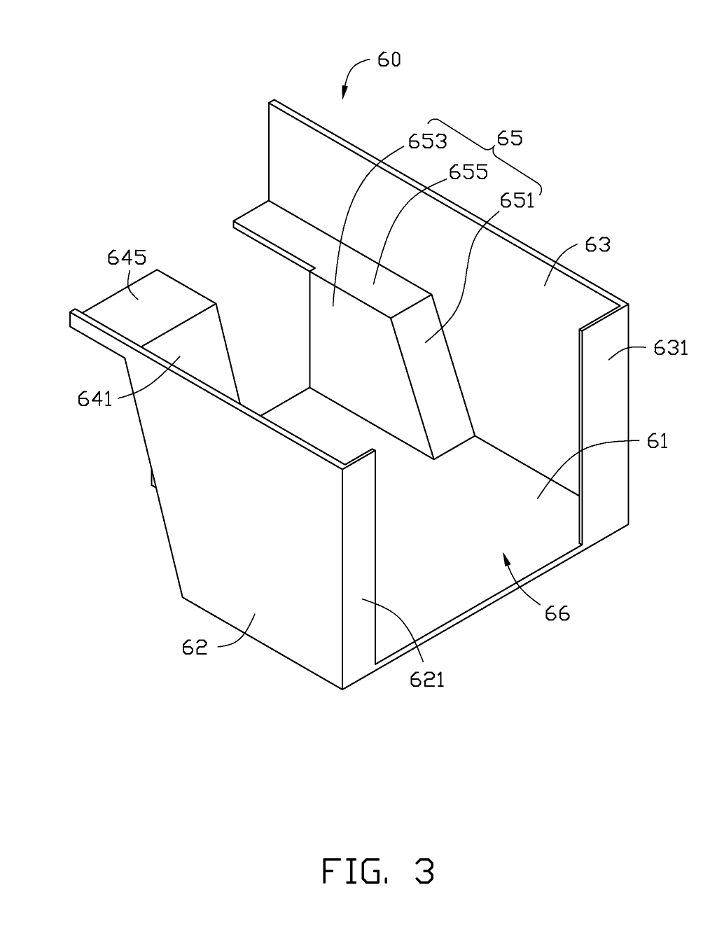

FIG. 3 illustrates the first air duct 60 further includes a first flange 621, a second flange 631 opposite to the first flange 621, and an air inlet 66. The first flange 621 extends perpendicularly from a side of the first sidewall 621 away from the first vent structure 64. The second flange 631 extends perpendicularly from a side of the second sidewall 631 away from the second vent structure 65. The first flange 621 and the second flange 631 are connected to the top panel 61. The air inlet 66 is cooperatively defined by the first flange 621, the second flange 631, and the top panel 61.

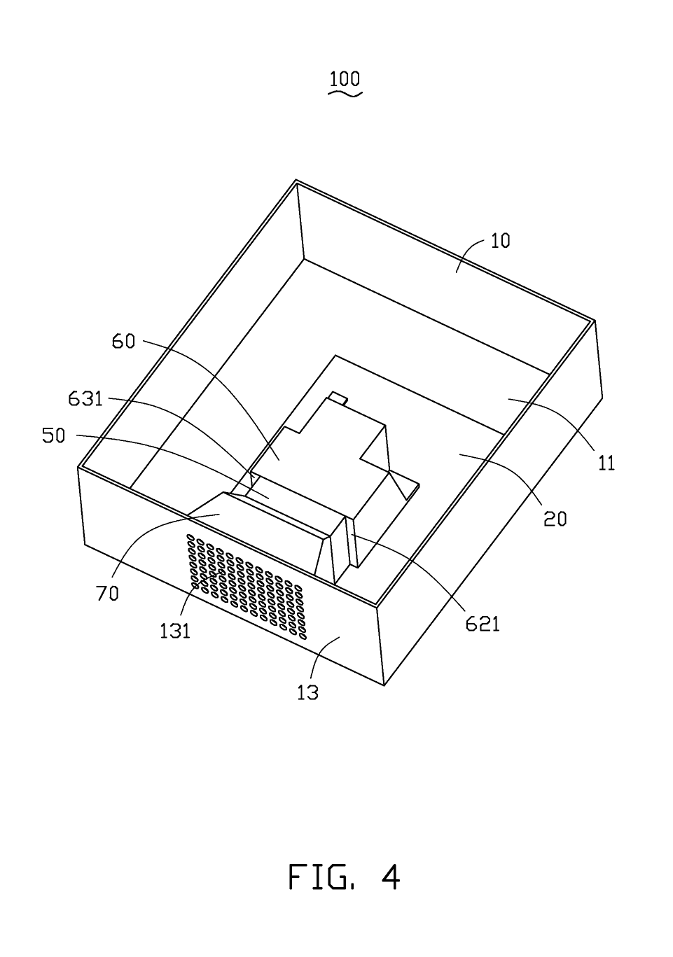

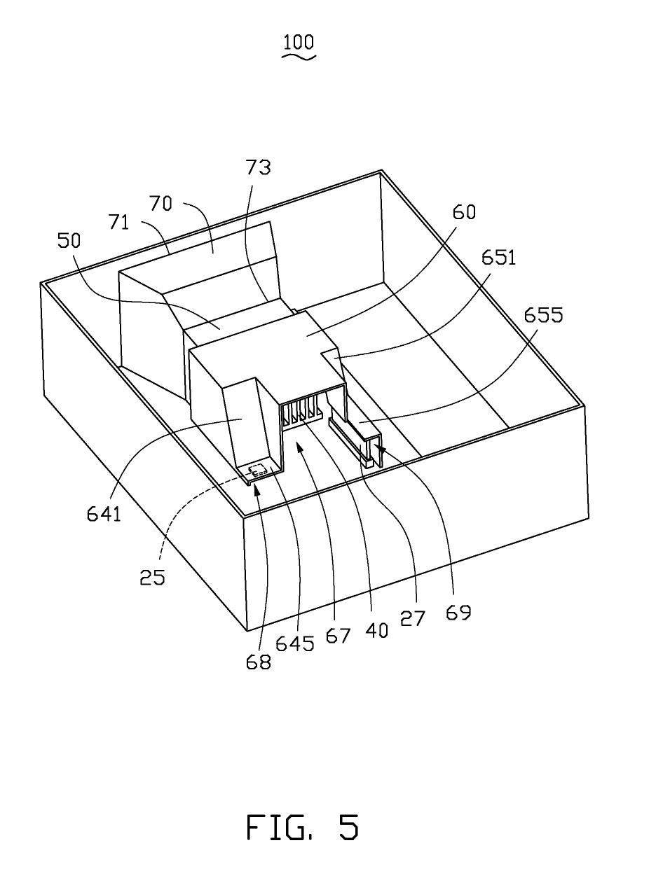

FIGS. 4 and 5 illustrate an assembly of the electronic device 100. The heat sink 40 is mounted on the circuit 20 and above the CPU 23. The first air duct 60 is mounted on the circuit 20 and includes a main air outlet channel 67, a first air outlet channel 68, and a second air outlet channel 69. The main air outlet channel 67, the first air outlet channel 68, and the second air outlet channel 69 are communicating with the air inlet 66. The main air outlet channel 67 is cooperatively defined by the top panel 61 and the main body 21, the first air outlet channel 68 is cooperatively defined by the first shielding panel 645 and the main body 21, and the second air outlet channel 69 is cooperatively defined by the second shielding panel 655 and the main body 21. The first air outlet channel 68 and the second air outlet channel 69 are located at two opposite sides of the main air outlet channel 67 and communicating with the main air outlet channel 67. In at least one embodiment, a first distance between the first shielding panel 645 and the main body 21 is less than a distance between the top panel 61 and the main body 21, a second distance between the second shielding panel 655 and the main body 21 is less than the distance between the top panel and the main body 21, and the first distance is less than the second distance. The heat sink 40 is received in the first air duct 60 and aligned with the main air outlet channel 67. The first component 25 is received in the first air outlet channel 68. The second component 27 is received in the second air outlet channel 69.

The second air duct 70 is mounted in the enclosure 10. The inlet vent 71 is aligned with the through holes 131, and the outlet vent 73 is aligned with the air inlet 66 of the first air duct 60. The fan 50 is mounted in the enclosure 10 and located between the first air duct 60 and the second air duct 70. A side of the fan 50 abuts against the second air duct 70, and another side of the fan 50 abuts against the first flange 621 and the second flange 631, thereby guiding airflow to the first air duct 60 completely from the second air duct 70. A part of the airflow is outflow from the main air outlet channel 67 to dissipate heat from the CPU 23, a part of the airflow is guided by the first guiding panel 641 to flow out from the first outlet channel 68 to dissipate heat from the first component 25, and another part of the airflow is guided by the second guiding panel 651 to flow out from the second outlet channel 69 to dissipate heat from the second component 27.

The embodiments shown and described above are only examples. Many details are often found in the art such as the other features of a heat dissipation device and an electronic device. Therefore, many such details are neither shown nor described. Even though numerous characteristics and advantages of the present technology have been set forth in the foregoing description, together with details of the structure and function of the present disclosure, the disclosure is illustrative only, and changes may be made in the details, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A heat dissipation device comprising:
a first air duct mounted on a circuit board and comprising:
a top panel;
a sidewall extending from the top panel; and
a vent structure connected to the top panel and the sidewall, the vent structure comprising:
a guiding panel extending from the top panel; and
a shielding panel extending from the guiding panel;
wherein the guiding panel is configured to guide airflow to a component located between the shielding panel and the circuit board to dissipate heat from the component.

2. The heat dissipation device of claim 1, wherein the vent structure further comprises a baffle extending from the top panel, and the guiding panel and the shielding panel are connected perpendicularly to the sidewall and the baffle.

3. The heat dissipation device of claim 2, wherein the sidewall and the baffle are substantially perpendicular to the top panel.

4. The heat dissipation device of claim 1, wherein an obtuse angle is defined by the guiding panel and the top panel.

5. The heat dissipation device of claim 1, wherein the shielding panel is substantially parallel to the top panel.

6. The heat dissipation device of claim 1, wherein the first air duct further comprises a flange extending from a side of the sidewall away from the vent structure.

7. The heat dissipation device of claim 6, further comprising a second air duct, wherein the first air duct comprises an air inlet, and the second air duct comprises an outlet vent aligned with the air inlet.

8. The heat dissipation device of claim 7, wherein the second air duct further comprises an inlet vent, and an area of the inlet vent is great than that of the outlet vent.

9. The heat dissipation device of claim 7, further comprising a fan, wherein the first air duct and the second air duct are located at two opposite sides of the fan.

10. The heat dissipation device of claim 1, further comprising a heat sink, wherein the heat sink is received in the first air duct.

11. An electronic device comprising:
a circuit board comprising a first component; and
a first air duct mounted on the circuit board, the first air duct comprising:
a top panel;
an air inlet;
a first shielding panel;
a main air outlet channel cooperatively defined by the top panel and the circuit board; and
a first air outlet channel cooperatively defined by the first shielding panel and the circuit board;
wherein the air inlet communicates with the main air outlet channel and the first air outlet channel, the first component is received in the first air outlet channel, and a first distance between the first shielding panel and the circuit board is less than a second distance between the top panel and the circuit board.

12. The electronic device of claim 11, wherein the first air duct further comprises a second shielding panel and a second air outlet channel, the second air outlet channel is cooperatively defined by the second shielding panel and the circuit board, the circuit board further comprises a second component received in the second air outlet channel, and the first air outlet channel and the second air outlet channel are located at two opposite sides of the main air outlet channel.

13. The electronic device of claim 12, wherein the main air outlet channel communicates with the first air outlet channel and the second air outlet channel.

14. The electronic device of claim 12, wherein a second distance between the second shielding panel and the circuit board is less than the distance between the top panel and the circuit board.

15. The electronic device of claim 14, wherein the first distance is less than the second distance.

16. The electronic device of claim 12, wherein the first shielding panel and the second shielding panel are substantially parallel to the circuit board.

17. The electronic device of claim 12, wherein the first air duct further comprises a first guiding panel extending slantingly to the first shielding panel from the top panel and a second guiding panel extending slantingly to the second shielding panel from the top panel, the first guiding panel is configured to guide airflow to the first air outlet channel, and the second guiding panel is configured to guide airflow to the second air outlet channel.

18. The electronic device of claim 17, wherein the first guiding panel is substantially parallel to the second guiding panel.

19. The electronic device of claim 11, further comprising a heat sink mounted on the circuit board, wherein the heat sink is received in the first air duct and aligned with the main air outlet channel.

20. The electronic device of claim 11, further comprises a second air duct and a fan, wherein the first air duct and the second air duct are located at two opposite sides of the fan.
